(19) United States
(12) Patent Application Publication
(10) Pub. No.: US 2025/0364212 A1
(43) Pub. Date: Nov. 27, 2025

(54) PLASMA PROCESSING APPARATUS

(71) Applicant: Tokyo Electron Limited, Tokyo (JP)

(72) Inventors: Yuichi TAKAHASHI, Kurokawa-gun (JP); Lifu LI, Kurokawa-gun (JP)

(21) Appl. No.: 19/293,201

(22) Filed: Aug. 7, 2025

Related U.S. Application Data
(63) Continuation of application No. PCT/JP2024/001413, filed on Jan. 19, 2024.

(30) Foreign Application Priority Data
Feb. 14, 2023 (JP) 2023-020626

(51) Int. Cl. H01J 37/32

(52) U.S. Cl. CPC H01J 37/32146; H01J 37/32541; H01J 37/32568; H01J 2237/3344

(57) ABSTRACT

To provide a technique capable of improving an in-plane uniformity of a substrate in plasma processing. A plasma processing apparatus includes a plasma processing chamber; a substrate support; a substrate chuck electrode; at least one ring chuck electrode; a substrate bias electrode; a ring bias electrode; a first voltage pulse generator; a second voltage pulse generator; and a switch configured to switch between a first connection state and a second connection state, the first connection state being a state where the first voltage pulse generator is electrically connected to the substrate bias electrode and the second voltage pulse generator is electrically connected to the ring bias electrode, and the second connection state being a state where the first voltage pulse generator is electrically connected to the ring bias electrode and the second voltage pulse generator is electrically connected to the substrate bias electrode.

### CROSS-REFERENCE TO RELATED APPLICATIONS

This application is a bypass continuation application of international application No. PCT/JP2024/001413 having an international filing date of Jan. 19, 2024 and designating the United States, the international application being based upon and claiming the benefit of priority from Japanese Patent Application No. 2023-20626, filed on Feb. 14, 2023, the entire contents of which are incorporated herein by reference.

### BACKGROUND

### Field

An exemplary embodiment of the present disclosure relates to a plasma processing apparatus.

### Description of Related Art

U.S. Patent Application Laid-Open No. 2022/0037119 discloses a technique of supplying an RF and a pulse voltage to a plurality of electrodes in a plasma processing apparatus.

### SUMMARY

A plasma processing apparatus in one exemplary embodiment of the present disclosure includes a plasma processing chamber; a substrate support that is disposed in the plasma processing chamber, the substrate support including a base, an electrostatic chuck that is disposed on the base and has a substrate support surface and a ring support surface, and at least one annular member that is disposed on the ring support surface such that a substrate disposed on the substrate support surface is surrounded; a substrate chuck electrode that is disposed below the substrate support surface in the electrostatic chuck; at least one ring chuck electrode that is disposed below the ring support surface in the electrostatic chuck; a substrate bias electrode that is disposed in the electrostatic chuck and is disposed below the substrate chuck electrode; a ring bias electrode that is disposed in the electrostatic chuck and is disposed below the at least one ring chuck electrode; a first voltage pulse generator configured to generate a sequence of first voltage pulses having a first voltage level; a second voltage pulse generator configured to generate a sequence of second voltage pulses having a second voltage level; and a switch configured to switch between a first connection state and a second connection state, the first connection state being a state where the first voltage pulse generator is electrically connected to the substrate bias electrode and the second voltage pulse generator is electrically connected to the ring bias electrode, and the second connection state being a state where the first voltage pulse generator is electrically connected to the ring bias electrode and the second voltage pulse generator is electrically connected to the substrate bias electrode.

### BRIEF DESCRIPTION OF DRAWINGS

FIG. 1 is a diagram for describing a configuration example of a plasma processing system.

FIG. 2 is a diagram for describing a configuration example of a capacitively coupled plasma processing apparatus.

FIG. 3 is a diagram for describing a configuration example of a substrate support and a DC power supply in a first exemplary embodiment.

FIG. 4 is a diagram for describing a configuration example of a bias electrode in a plan view.

FIG. 5 is a diagram illustrating an example of a voltage pulse.

FIG. 6 is a diagram for describing a configuration example of a switch.

FIG. 7 is a diagram for describing a fluctuation of a plasma sheath on a substrate.

FIG. 8 is a diagram for describing a fluctuation of the plasma sheath on the substrate.

FIG. 9 is a diagram for describing a fluctuation of the plasma sheath on the substrate in a case where a thickness of a ring assembly is thick.

FIG. 10 is a diagram for describing a fluctuation of the plasma sheath on the substrate in a case where the thickness of the ring assembly is reduced.

FIG. 11 is a diagram for describing another disposition example of a ring bias electrode.

FIG. 12 is a diagram for describing another disposition example of the ring bias electrode.

FIG. 13 is a diagram for describing a configuration example of a substrate support and a DC power supply in a second exemplary embodiment.

FIG. 14 is a diagram for describing a configuration example of the substrate support and the DC power supply in the second exemplary embodiment.

### DETAILED DESCRIPTION

Hereinafter, each embodiment of the present disclosure will be described.

In an exemplary embodiment, a plasma processing apparatus is provided, the plasma processing apparatus including: a plasma processing chamber; a substrate support that is disposed in the plasma processing chamber, the substrate support including a base, an electrostatic chuck that is disposed on the base and has a substrate support surface and a ring support surface, and at least one annular member that is disposed on the ring support surface such that a substrate disposed on the substrate support surface is surrounded; a substrate chuck electrode that is disposed below the substrate support surface in the electrostatic chuck; at least one ring chuck electrode that is disposed below the ring support surface in the electrostatic chuck; a substrate bias electrode that is disposed in the electrostatic chuck and is disposed below the substrate chuck electrode; a ring bias electrode that is disposed in the electrostatic chuck and is disposed below the at least one ring chuck electrode; a first voltage pulse generator configured to generate a sequence of first voltage pulses having a first voltage level; a second voltage pulse generator configured to generate a sequence of second voltage pulses having a second voltage level; and a switch configured to switch between a first connection state and a second connection state, the first connection state being a state where the first voltage pulse generator is electrically connected to the substrate bias electrode and the second voltage pulse generator is electrically connected to the ring bias electrode, and the second connection state being a state where the first voltage pulse generator is electrically connected to the ring bias electrode and the second voltage pulse generator is electrically connected to the substrate bias electrode.

In one exemplary embodiment, the switch includes a rotatable member, and a first wiring and a second wiring attached to the rotatable member, the switch is configured to switch between the first connection state and the second connection state by rotation of the rotatable member, the first connection state is a state where the first voltage pulse generator is electrically connected to the substrate bias electrode via the first wiring, and the second voltage pulse generator is electrically connected to the ring bias electrode via the second wiring, and the second connection state is a state where the first voltage pulse generator is electrically connected to the ring bias electrode via the first wiring, and the second voltage pulse generator is electrically connected to the substrate bias electrode via the second wiring.

In one exemplary embodiment, the switch is an electric circuit.

In one exemplary embodiment, the first voltage level and the second voltage level have a negative polarity.

In one exemplary embodiment, an absolute value of the first voltage level is larger than an absolute value of the second voltage level.

In one exemplary embodiment, the substrate bias electrode and the ring bias electrode are disposed at the same height.

In one exemplary embodiment, the substrate bias electrode and the ring bias electrode are disposed at heights different from each other.

In one exemplary embodiment, the ring bias electrode is disposed at a position lower than the substrate bias electrode.

In one exemplary embodiment, the substrate bias electrode has an outer edge region, and the ring bias electrode has an inner edge region that overlaps the outer edge region of the substrate bias electrode in a longitudinal direction.

In one exemplary embodiment, the ring chuck electrode includes an inner ring chuck electrode to which a first ring chuck voltage having a first polarity is applied, and an outer ring chuck electrode to which a second ring chuck voltage having a second polarity is applied.

In an exemplary embodiment, a plasma processing apparatus is provided, the plasma processing apparatus including: a plasma processing chamber; a substrate support that is disposed in the plasma processing chamber, the substrate support including a base, an electrostatic chuck that is disposed on the base and has a substrate support surface and a ring support surface, and at least one annular member that is disposed on the ring support surface such that a substrate disposed on the substrate support surface is surrounded; a substrate chuck electrode that is disposed below the substrate support surface in the electrostatic chuck; at least one ring chuck electrode that is disposed below the ring support surface in the electrostatic chuck; a substrate bias electrode that is disposed in the electrostatic chuck and is disposed below the substrate chuck electrode; a ring bias electrode that is disposed in the electrostatic chuck and is disposed below the at least one ring chuck electrode; a first DC power supply configured to generate a first primary DC signal having a first primary voltage level; a second DC power supply configured to generate a second primary DC signal having a second primary voltage level; a voltage adder that is configured to generate a first secondary DC signal having a first secondary voltage level and a second secondary DC signal having a second secondary voltage level from the first primary DC signal and the second primary DC signal, and is configured to switch between a first generation state and a second generation state, the first generation state being a state where the first secondary DC signal is generated such that the first secondary voltage level has the same voltage level as the first primary voltage level, and the second secondary DC signal is generated such that the second secondary voltage level has a voltage level obtained by adding the first primary voltage level and the second primary voltage level, and the second generation state being a state where the first secondary DC signal is generated such that the first secondary voltage level has a voltage level obtained by adding the first primary voltage level and the second primary voltage level, and the second secondary DC signal is generated such that the second secondary voltage level has the same voltage level as the first primary voltage level; a first voltage pulse generator that is electrically connected to the substrate bias electrode and is configured to generate a sequence of first voltage pulses having the first secondary voltage level from the first secondary DC signal; and a second voltage pulse generator that is electrically connected to the ring bias electrode and is configured to generate a sequence of second voltage pulses having the second secondary voltage level from the second secondary DC signal.

In one exemplary embodiment, the first primary voltage level and the second primary voltage level have a negative polarity.

In one exemplary embodiment, an absolute value of the first primary voltage level is larger than an absolute value of the second primary voltage level.

In one exemplary embodiment, the absolute value of the first primary voltage level is 5 times or more the absolute value of the second primary voltage level.

In one exemplary embodiment, the substrate bias electrode and the ring bias electrode are disposed at the same height.

In one exemplary embodiment, the substrate bias electrode and the ring bias electrode are disposed at heights different from each other.

In one exemplary embodiment, the ring bias electrode is disposed at a position lower than the substrate bias electrode.

In one exemplary embodiment, the substrate bias electrode has an outer edge region, and the ring bias electrode has an inner edge region that overlaps the outer edge region of the substrate bias electrode in a longitudinal direction.

In one exemplary embodiment, the ring chuck electrode includes an inner ring chuck electrode to which a first ring chuck voltage having a first polarity is applied, and an outer ring chuck electrode to which a second ring chuck voltage having a second polarity is applied.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Example of Plasma Processing Apparatus>

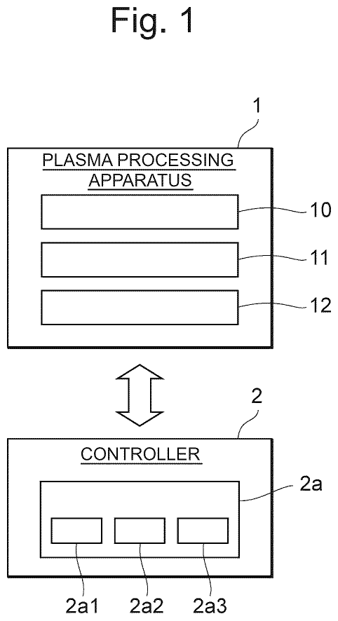

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is disposed in the plasma processing space and has a substrate support surface for supporting a substrate.

The plasma generator 12 is configured such that a plasma is formed from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHZ. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured such that each element of the plasma processing apparatus 1 is controlled such that the various steps described here are executed. In an embodiment, a part or the entirety of the controller 2 may be included in the plasma processing apparatus 1. The controller 2 may include, for example, a computer 2a. The computer 2a may include, for example, a processor (central processing unit (CPU)) 2a1, a storage 2a2, and a communication interface 2a3. The processor 2a1 may be configured to read out a program from the storage 2a2 and execute the read out program such that various control operations are performed. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a, or may be a communication line connected to the communication interface 2a3. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

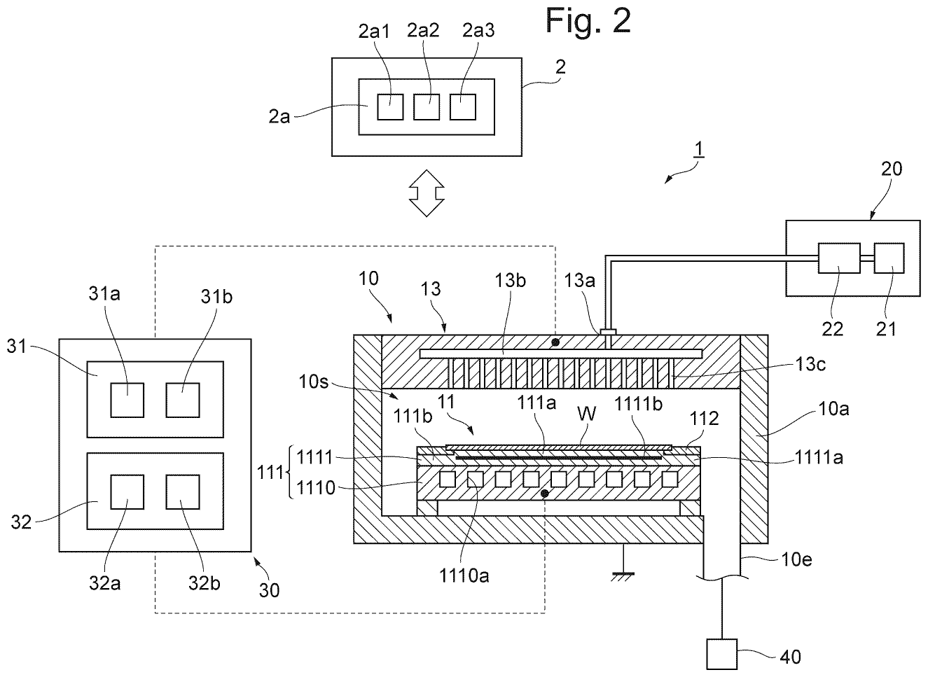

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured such that at least one processing gas is introduced into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly (edge ring assembly) 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 such that the substrate W on the center region 111a of the main body 111 is surrounded. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. In addition, an RF or DC electrode may be disposed in the ceramic member 1111a, and in this case, the RF or DC electrode functions as the lower electrode. In a case where a bias RF signal or a DC signal, described later, is connected to the RF or DC electrode, the RF or DC electrode is also referred to as a bias electrode. Both of the conductive member of the base 1110 and the RF or DC electrode may function as two lower electrodes.

The ring assembly 112 includes one or more annular members. In an embodiment, one or more annular members include one or more edge rings and at least one cover ring. The edge ring is formed of a conductive material or an insulating material, and the cover ring is formed of an insulating material.

In addition, the substrate support 11 may include a temperature-controlled module configured such that at least one of the electrostatic chuck 1111, the ring assembly 112, and the substrate is adjusted to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or more heaters are disposed in the ceramic member 1111a of the electrostatic chuck 1111. Further, the substrate support 11 may include a heat transfer gas supply configured such that the heat transfer gas is supplied to a gap between a back surface of the substrate W and the center region 111a.

The shower head 13 is configured such that at least one processing gas is introduced from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes an upper electrode. In addition to the shower head 13, the gas introducer may include one or more side gas injectors (SGI) attached to one or more opening portions formed on the side wall 10a.

The gas supply 20 may include at least one gas source 21 and at least one flow rate controller 22. In an embodiment, the gas supply 20 is configured such that at least one processing gas is supplied to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes an RF power supply 31 coupled to the plasma processing chamber 10 via at least one impedance matching circuit. The RF power supply 31 is configured such that at least one RF signal (RF power), such as a source RF signal and a bias RF signal, is supplied to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma can be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured such that a source RF signal (source RF power) for plasma formation is generated. In an embodiment, the source RF signal has a frequency in the range of 10 MHz to 150 MHz. In an embodiment, the first RF generator 31a may be configured such that a plurality of source RF signals having different frequencies are generated. The generated one or more source RF signals are supplied to at least one lower electrode and/or at least one upper electrode.

The second RF generator 31b is coupled to at least one lower electrode via at least one impedance matching circuit and is configured such that the bias RF signal (bias RF power) is generated. The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured such that a plurality of bias RF signals having different frequencies are generated. The generated one or more bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured such that the first DC signal is generated. The generated first DC signal is applied to at least one lower electrode. In an embodiment, the second DC generator 32b is connected to at least one upper electrode and is configured such that a second DC signal is generated. The generated second DC signal is applied to at least one upper electrode.

In various embodiments, the first and second DC signals may be pulsed. In this case, a sequence of voltage pulses based on DC is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or more voltage pulses of a positive polarity and one or more voltage pulses of a negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### First Exemplary Embodiment

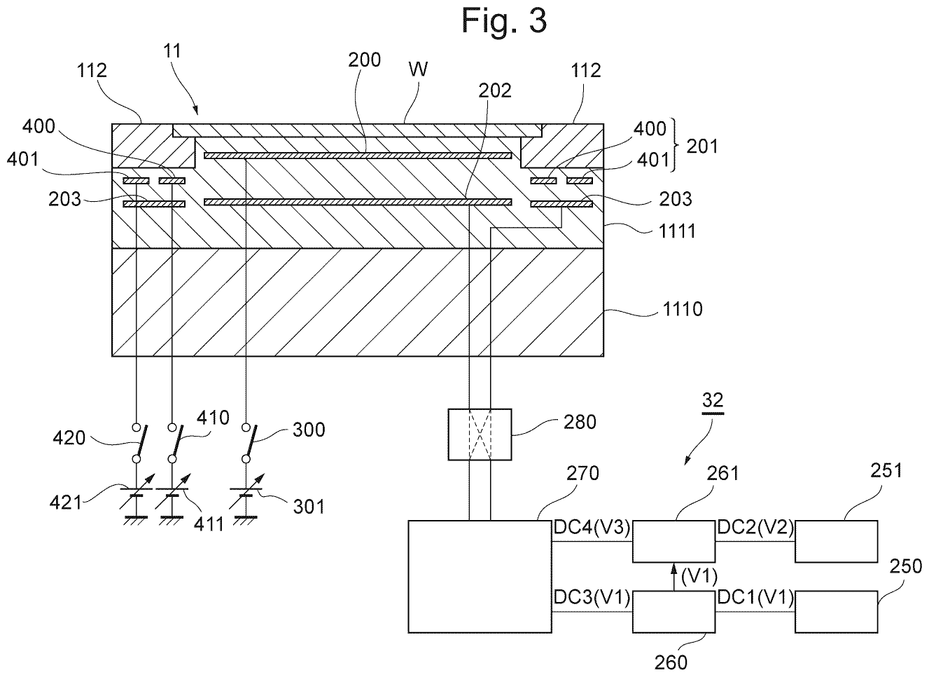

A first exemplary embodiment of the above-described plasma processing apparatus 1 will be described. FIG. 3 is a diagram for describing a configuration example of the substrate support 11 and a DC power supply 32 in the first exemplary embodiment. In an embodiment, the substrate support 11 has a substrate chuck electrode 200, a ring chuck electrode 201, a substrate bias electrode 202, and a ring bias electrode 203 inside the electrostatic chuck 1111. The substrate chuck electrode 200 and the ring chuck electrode 201 may be an example of the above-described electrostatic electrode 1111b.

In an embodiment, the DC power supply 32 includes a first DC power supply 250, a second DC power supply 251, a first voltage pulse generator 260, a second voltage pulse generator 261, an impedance matching box (matcher) 270, and a switch 280.

The substrate chuck electrode 200 may be disposed below the substrate support surface in the electrostatic chuck 1111. In an embodiment, the substrate chuck electrode 200 has a circular shape. In an embodiment, the substrate chuck electrode 200 is connected to a direct current (DC) power supply 301 via a switch 300. When a direct current voltage from the direct current power supply 301 is applied to the substrate chuck electrode 200, an electrostatic attraction force (Coulomb force) is generated between the substrate chuck electrode 200 and the substrate W. The substrate W is drawn to the electrostatic chuck 1111 by the electrostatic attraction force thereof and is held by suction on the substrate support surface.

In an embodiment, the ring chuck electrode 201 may be disposed below the ring support surface in the electrostatic chuck 1111. In an embodiment, the ring chuck electrode 201 includes an inner ring chuck electrode 400 and an outer ring chuck electrode 401. In an embodiment, the inner ring chuck electrode 400 is connected to a direct current power supply 411 via a switch 410. In an embodiment, the outer ring chuck electrode 401 is disposed outside the inner ring chuck electrode 400. In an embodiment, the outer ring chuck electrode 401 is connected to a direct current power supply 421 via a switch 420. In an embodiment, in the ring chuck electrode 201, a potential difference is generated between the inner ring chuck electrode 400 and the outer ring chuck electrode 401, and the ring assembly 112 is held by suction on the ring support surface by the potential difference. In an embodiment, a polarity of a first ring chuck voltage applied to the inner ring chuck electrode 400 is different from a polarity of a second ring chuck voltage applied to the outer ring chuck electrode 401.

In an embodiment, the substrate bias electrode 202 may be disposed below the substrate support surface in the electrostatic chuck 1111 the substrate support surface is overlapped in a longitudinal direction. The ring bias electrode 203 may be disposed below the ring support surface the ring support surface is overlapped in the electrostatic chuck 1111 in the longitudinal direction. The substrate bias electrode 202 and the ring bias electrode 203 may be disposed at the same height.

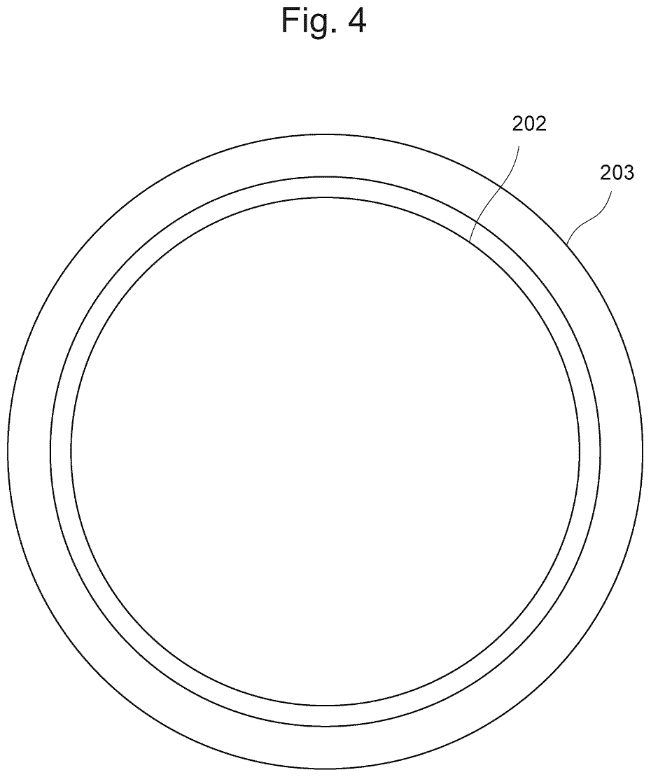

As illustrated in FIG. 4, the substrate bias electrode 202 may have a circular shape. The ring bias electrode 203 may have a toroidal shape having a width in a radial direction. In an embodiment, the ring bias electrode 203 has a larger diameter than the substrate bias electrode 202 and is disposed outside the substrate bias electrode 202.

As illustrated in FIG. 3, the first DC power supply 250 may generate a first DC signal DC1 having a first primary voltage level V1. The first primary voltage level V1 may have a negative polarity. The first DC power supply 250 is electrically connected to the first voltage pulse generator 260. The generated first DC signal DC1 may be supplied to the first voltage pulse generator 260.

The second DC power supply 251 may generate a second DC signal DC2 having a second primary voltage level V2. The second primary voltage level V2 may have the negative polarity. The second DC power supply 251 is electrically connected to the second voltage pulse generator 261. The generated second DC signal DC2 may be supplied to the second voltage pulse generator 261. An absolute value of the first primary voltage level V1 may be larger than an absolute value of the second primary voltage level V2, and the absolute value of the first primary voltage level V1 may be 5 times or more the absolute value of the second primary voltage level V2.

The first voltage pulse generator 260 may generate a first voltage pulse signal DC3 having a first voltage level V1 from the first DC signal DC1 supplied from the first DC power supply 250. The first voltage level may have the same voltage level (V1) as the first primary voltage level. The first voltage pulse signal DC3 may include a sequence of the first voltage pulses. The first voltage pulse generator 260 is electrically connected to the switch 280 via the impedance matching box 270. The generated first voltage pulse signal DC3 may be supplied to the switch 280. The first voltage pulse generator 260 is electrically connected to the second voltage pulse generator 261, and may supply the first DC signal DC1 supplied from the first DC power supply 250 to the second voltage pulse generator 261.

The second voltage pulse generator 261 may generate a second voltage pulse signal DC4 having a second voltage level V3 (V1+V2) obtained by adding the first primary voltage level V1 and the second primary voltage level V2 from the second DC signal DC2 supplied from the second DC power supply 251 and the first DC signal DC1 supplied from the first DC power supply 250 (first voltage pulse generator 260). The absolute value of the second voltage level V3 may be larger than the absolute value of the first voltage level V1. The second voltage pulse signal DC4 may include a sequence of the second voltage pulses. The second voltage pulse generator 261 is electrically connected to the switch 280 via the impedance matching box 270. The generated second voltage pulse signal DC4 may be supplied to the switch 280. The second voltage level may be the same voltage level (V2) as the second primary voltage level as long as the second voltage level is larger than the first voltage level.

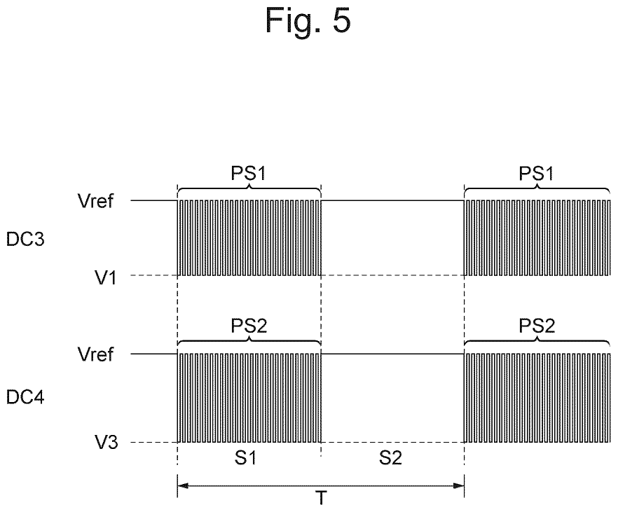

FIG. 5 illustrates an example of the first and second voltage pulse signals DC3 and DC4. The first voltage pulse signal DC3 may have a sequence PS1 of voltage pulses having the first voltage level V1 during a first state S1 within a repetition period T, and may continuously have a reference voltage level Vref during a second state S2 within the repetition period T. That is, during the second state S2, the first voltage pulse signal DC3 may be maintained at the reference voltage level Vref. An absolute value of the reference voltage level Vref is smaller than the absolute value of the first voltage level V1. In an embodiment, the first voltage level V1 has the negative polarity. In an embodiment, the reference voltage level Vref has a zero voltage level.

The second voltage pulse signal DC4 may have a sequence PS2 of voltage pulses having the second voltage level V3 during the first state S1 in the repetition period T, and may continuously have the reference voltage level Vref during the second state S2 in the repetition period T. That is, during the second state S2, the second voltage pulse signal DC4 may be maintained at the reference voltage level Vref. The absolute value of the reference voltage level Vref is smaller than the absolute value of the second voltage level V3. In an embodiment, the second voltage level V3 has the negative polarity, and the reference voltage level Vref has the zero voltage level.

In an embodiment, the switch 280 illustrated in FIG. 3 is configured to switch an electrical connection state. In an embodiment, the switch 280 is switchable between a first connection state where the first voltage pulse generator 260 is electrically connected to the substrate bias electrode 202 and the second voltage pulse generator 261 is electrically connected to the ring bias electrode 203, and a second connection state where the first voltage pulse generator 260 is electrically connected to the ring bias electrode 203 and the second voltage pulse generator 261 is electrically connected to the substrate bias electrode 202.

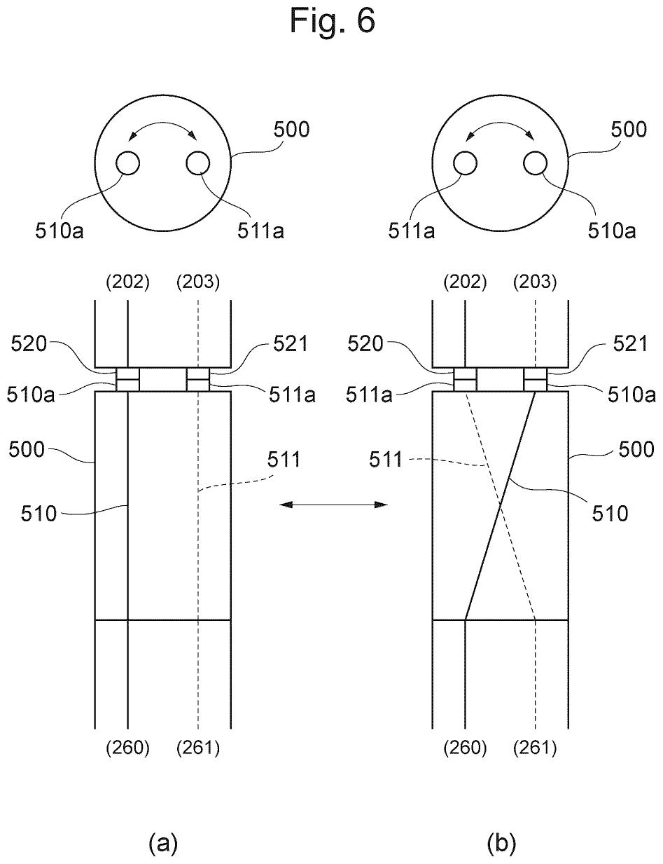

FIG. 6 is a diagram describing a configuration example of the switch 280. The switch 280 may mechanically switch between the first connection state and the second connection state. In an embodiment, the switch 280 may include a rotatable member 500 and a first wiring 510 and a second wiring 511 attached to the rotatable member 500. The rotatable member 500 can rotate by 180 degrees to exchange a position of a terminal 510a of the first wiring 510 and a position of a terminal 511a of the second wiring 511.

The rotatable member 500 may switch between a first connection state (a state of (a) in FIG. 6) and a second connection state (a state of (b) in FIG. 6) by rotation. The first connection state (a) is a state where the terminal 510a of the first wiring 510 and the wiring terminal 520 connected to the substrate bias electrode 202 are connected to each other, the first voltage pulse generator 260 and the substrate bias electrode 202 are electrically connected to each other, the terminal 511a of the second wiring 511 and the wiring terminal 521 connected to the ring bias electrode 203 are connected to each other, and the second voltage pulse generator 261 and the ring bias electrode 203 are electrically connected to each other. The second connection state (b) is a state where the terminal 510a of the first wiring 510 and the wiring terminal 521 of the ring bias electrode 203 are connected to each other, the first voltage pulse generator 260 and the ring bias electrode 203 are electrically connected to each other, the terminal 511a of the second wiring 511 and the wiring terminal 520 of the substrate bias electrode 202 are connected to each other, and the second voltage pulse generator 261 and the substrate bias electrode 202 are electrically connected to each other.

In an embodiment, in the first connection state (a), the first voltage pulse having the first voltage level V1, which is generated by the first voltage pulse generator 260, is applied to the substrate bias electrode 202 illustrated in FIG. 3, and the second voltage pulse having the second voltage level V3, which is generated by the second voltage pulse generator 261, is applied to the ring bias electrode 203. In the second connection state (b), the second voltage pulse having the second voltage level V3, which is generated by the second voltage pulse generator 261, is applied to the substrate bias electrode 202, and the first voltage pulse having the first voltage level V1, which is generated by the first voltage pulse generator 260, is applied to the ring bias electrode 203.

### <Example of Plasma Processing Method>

A plasma processing method includes etching processing of etching a film on the substrate W using plasma. In an embodiment, the plasma processing method is executed by a controller 2 in the plasma processing apparatus 1.

First, the substrate W is transported into the chamber 10 by the transport arm, placed on the substrate support 11 by a lifter, and is held by suction on the substrate support 11 as illustrated in FIG. 2.

Next, the processing gas is supplied to the shower head 13 by the gas supply 20, and is supplied from the shower head 13 to the plasma processing space 10s. The processing gas supplied at this time includes a gas that generates an active species required for the etching processing of the substrate W.

One or more RF signals are supplied from an RF power supply 31 to an upper electrode and/or the lower electrode. The atmosphere in the plasma processing space 10s may be exhausted from a gas exhaust port 10e, and the inside of the plasma processing space 10s may be depressurized. As a result, plasma is formed on the substrate support 11 of the plasma processing space 10s, and the substrate W is subjected to the etching processing.

During the plasma formation, the voltage pulse signals are supplied from the first voltage pulse generator 260 and the second voltage pulse generator 261 illustrated in FIG. 3 to the substrate bias electrode 202 and the ring bias electrode 203, and the voltage pulses are applied to the substrate bias electrode 202 and the ring bias electrode 203, respectively. As a result, the bias signal based on the voltage pulse is generated on the substrate W and the ring assembly 112, and ion components in the plasma on the substrate W are drawn to the substrate W side.

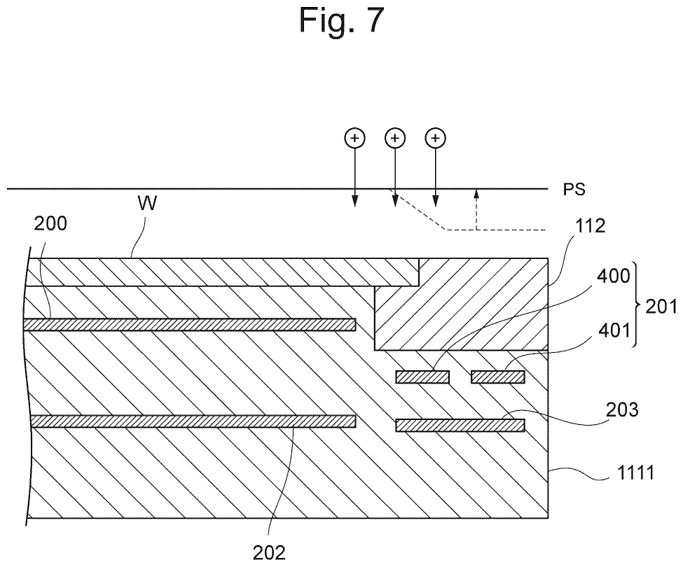

In an embodiment, as illustrated in FIG. 7, in a case where a plasma sheath PS generated on an upper side of the substrate W and the ring assembly 112 is lower than the upper side of the substrate W on an upper side of the ring assembly 112, the voltage level of the voltage pulse applied to the ring bias electrode 203 is set to be higher than the voltage level of the voltage pulse applied to the substrate bias electrode 202. That is, the first connection state (a) is switched by the switch 280, the first voltage pulse signal DC3 having the first voltage level V1 is supplied from the first voltage pulse generator 260 to the substrate bias electrode 202, and the second voltage pulse signal DC4 having the second voltage level V3 larger than the first voltage level V1 is supplied from the second voltage pulse generator 261 to the ring bias electrode 203. As a result, the plasma sheath PS approaches the substrate W in parallel (horizontally), and an angle (ion incidence angle) at which the ion component of the plasma enters the substrate W in a plane of the substrate W approaches perpendicular to the substrate W.

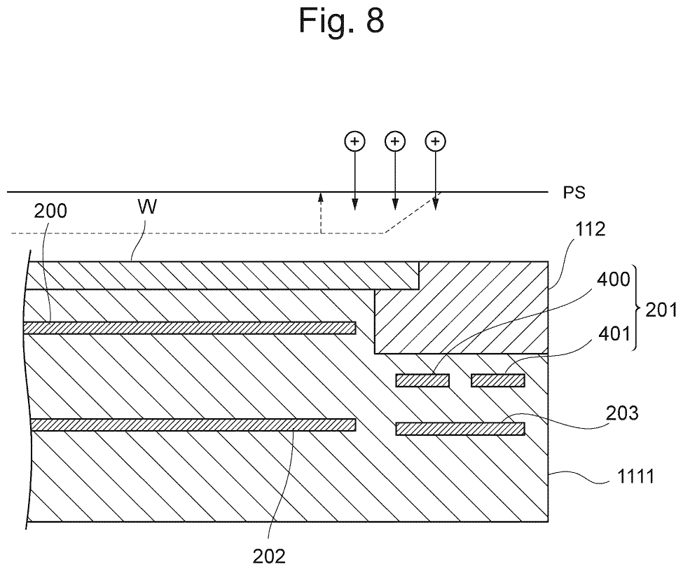

In an embodiment, as illustrated in FIG. 8, in a case where the plasma sheath PS is higher than the upper side of the substrate W on the upper side of the ring assembly 112, the voltage level of the voltage pulse applied to the substrate bias electrode 202 is set to be higher than the voltage level of the voltage pulse applied to the ring bias electrode 203. That is, the second connection state (b) is switched by the switch 280, the first voltage pulse signal DC3 having the first voltage level V1 is supplied from the first voltage pulse generator 260 to the ring bias electrode 203, and the second voltage pulse signal DC4 having the second voltage level V3 higher than the first voltage level V1 is supplied from the second voltage pulse generator 261 to the substrate bias electrode 202. As a result, the plasma sheath PS approaches the substrate W in parallel (horizontally), and an angle (ion incidence angle) at which the ion component of the plasma enters the substrate W in a plane of the substrate W approaches perpendicular to the substrate W.

According to the present exemplary embodiment, the plasma processing apparatus 1 includes the substrate support 11, the substrate bias electrode 202, the ring bias electrode 203, the first voltage pulse generator 260, the second voltage pulse generator 261, and the switch 280. As a result, the ion incidence angle in the plane of the substrate W in the plasma processing can be controlled. As a result, the in-plane uniformity of the substrate in the plasma processing can be improved.

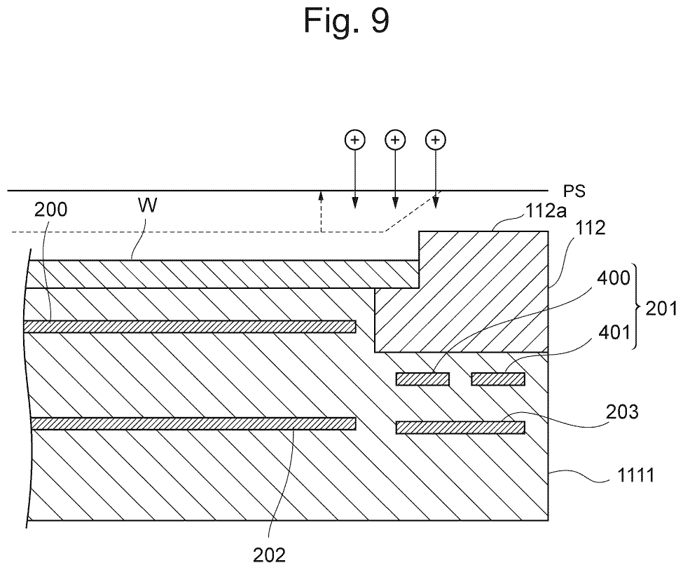

According to the present exemplary embodiment, as illustrated in FIG. 9, the thickness of the ring assembly 112 at the time of shipment (initial time) can be increased. In this case, since the position of an upper surface 112a of the ring assembly 112 is high, the plasma sheath PS is high on the upper side of the ring assembly 112. Therefore, the second connection state (b) is switched by the switch 280, and the voltage level of the voltage pulse applied to the substrate bias electrode 202 is set to be higher than the voltage level of the voltage pulse applied to the ring bias electrode 203. As a result, the plasma sheath PS approaches the substrate W in parallel (horizontally), and the angle (ion incidence angle) at which the ion component of the plasma enters the substrate W in the plane of the substrate W approaches perpendicular to the substrate W.

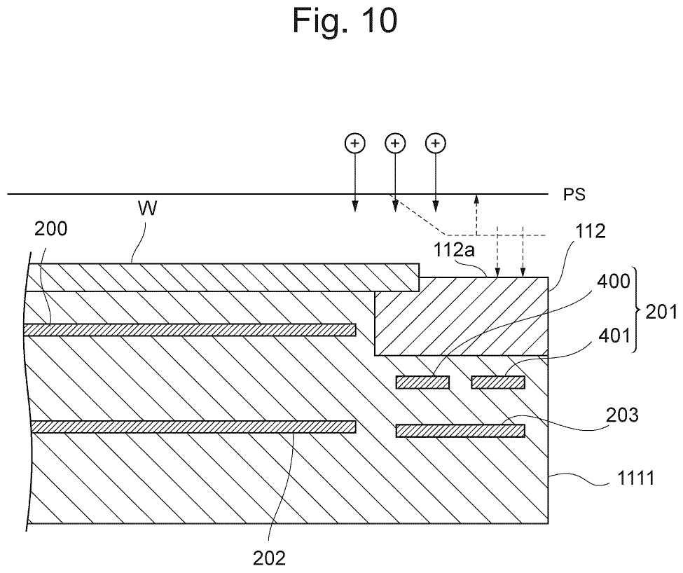

In addition, as illustrated in FIG. 10, in a case where the ring assembly 112 is worn out by the plasma processing and the thickness of the ring assembly 112 is reduced, the position of the upper surface 112a of the ring assembly 112 is lowered, and the plasma sheath PS is low on the upper side of the ring assembly 112. In this case, the first connection state (a) is switched by the switch 280, and the voltage level of the voltage pulse applied to the ring bias electrode 203 is higher than the voltage level of the voltage pulse applied to the substrate bias electrode 202. As a result, the plasma sheath PS approaches the substrate W in parallel (horizontally), and the angle (ion incidence angle) at which the ion component of the plasma enters the substrate W in the plane of the substrate W approaches perpendicular to the substrate W. By increasing the thickness of the ring assembly 112 at the initial time and controlling the plasma sheath PS according to the subsequent wear of the ring assembly 112, it is possible to extend a use period (life) of the ring assembly 112 and to reduce the number of times of exchange of the ring assembly 112.

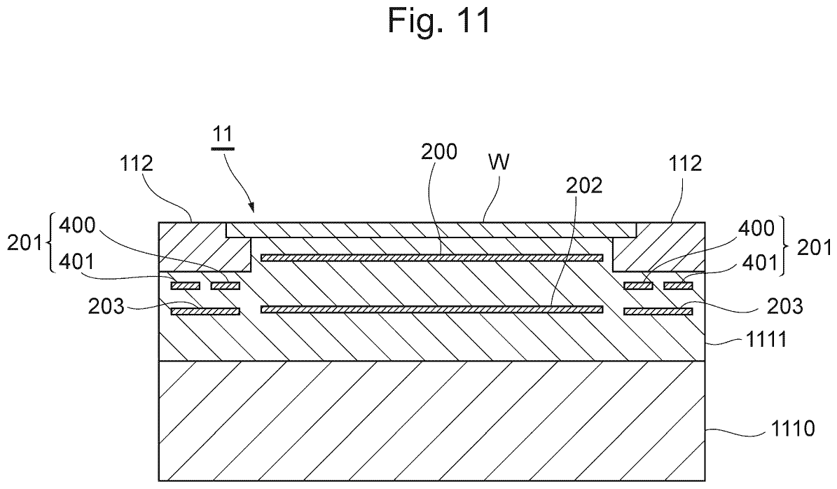

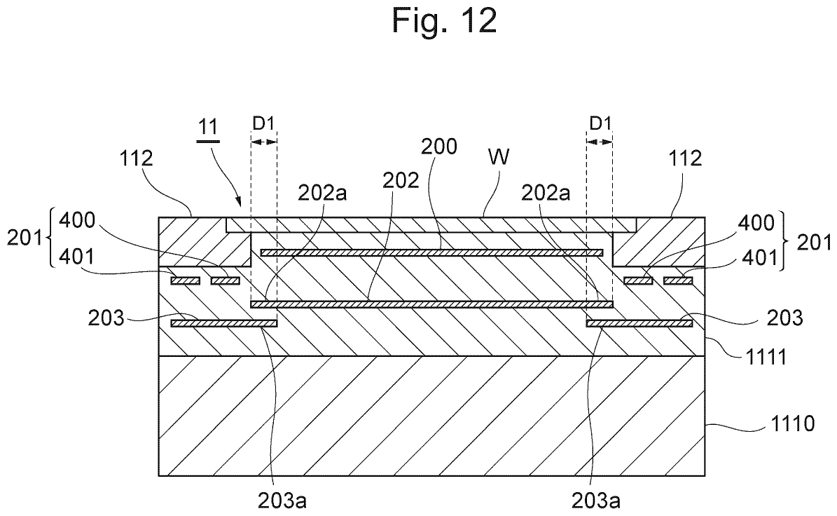

In the above-described embodiment, as illustrated in FIG. 11, the substrate bias electrode 202 and the ring bias electrode 203 of the substrate support 11 may be disposed at heights different from each other. In an embodiment, the ring bias electrode 203 may be disposed at a position lower than the substrate bias electrode 202. In addition, in an embodiment, as illustrated in FIG. 12, an outer edge region 202a of the substrate bias electrode 202 may overlap an inner edge region 203a of the ring bias electrode 203 in the longitudinal direction. A width D1 of the overlapping portion between the substrate bias electrode 202 and the ring bias electrode 203 in the radial direction may be 9 mm to 11 mm.

The ring bias electrode 203 may be disposed at a position higher than the substrate bias electrode 202.

In the above-described embodiment, the switch 280 mechanically switches the first connection state and the second connection state, and an electric circuit that electrically switches the first connection state and the second connection state may be used.

### Second Exemplary Embodiment

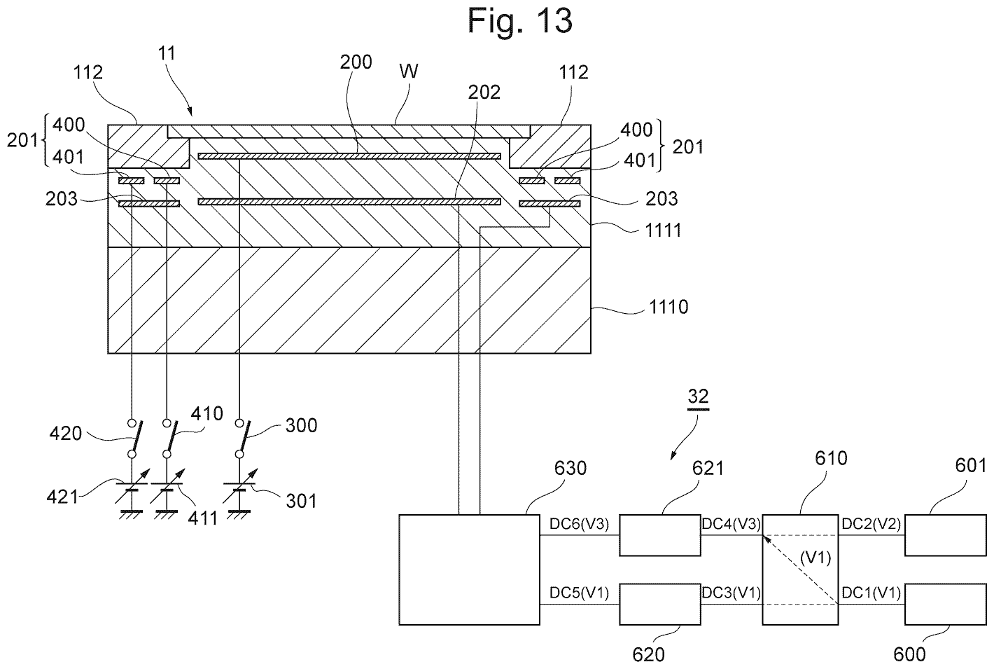

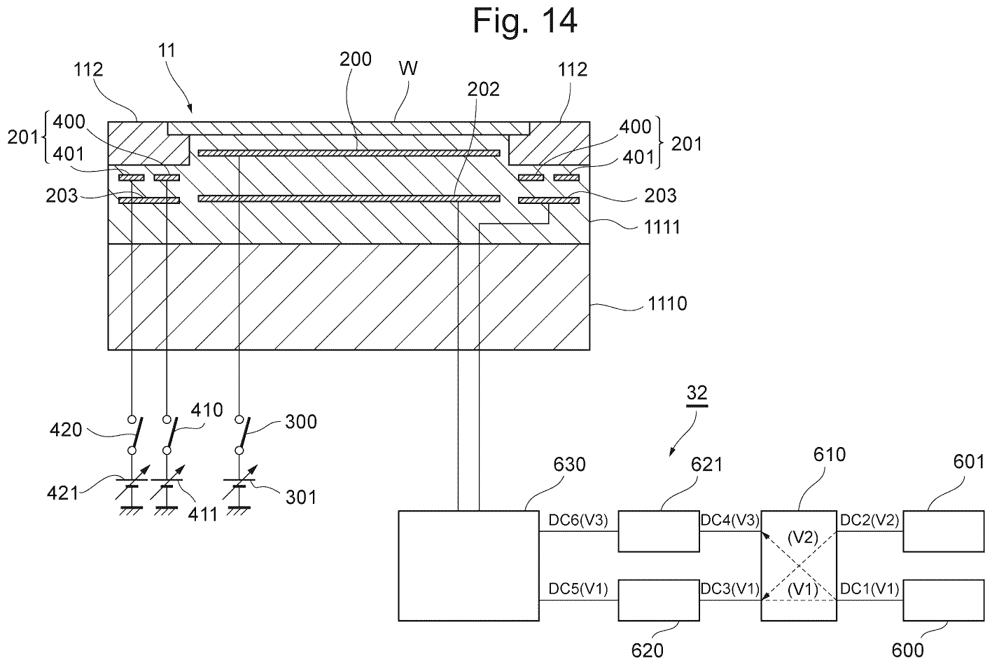

A second exemplary embodiment of the plasma processing apparatus 1 will be described. FIGS. 13 and 14 are diagrams for describing configuration examples of the substrate support 11 and the DC power supply 32 in the second exemplary embodiment. In an embodiment, the substrate support 11 may be the same as in the above-described first exemplary embodiment.

In an embodiment, the DC power supply 32 includes a first DC power supply 600, a second DC power supply 601, a voltage adder 610, a first voltage pulse generator 620, a second voltage pulse generator 621, and an impedance matching box 630.

The first DC power supply 600 may generate a first primary DC signal DC1 having the first primary voltage level V1. The first primary voltage level V1 may have a negative polarity. The first DC power supply 600 is electrically connected to the voltage adder 610. The generated first primary DC signal DC1 may be supplied to the voltage adder 610.

The second DC power supply 601 may generate the second primary DC signal DC2 having the second primary voltage level V2. The second primary voltage level V2 may have the negative polarity. The second DC power supply 601 is electrically connected to the voltage adder 610. The generated second primary DC signal DC2 may be supplied to the voltage adder 610. An absolute value of the first primary voltage level V1 may be larger than an absolute value of the second primary voltage level V2, and the absolute value of the first primary voltage level V1 may be 5 times or more the absolute value of the second primary voltage level V2.

The voltage adder 610 may generate a first secondary DC signal DC3 having the first secondary voltage level and a second secondary DC signal DC4 having the second secondary voltage level by using the first primary DC signal DC1 and the second primary DC signal DC2.

In an embodiment, the voltage adder 610 is configured to switch between the first generation state and the second generation state. In the first generation state, as illustrated in FIG. 13, the first secondary DC signal DC3 having the first secondary voltage level V1, which is the same voltage level as the first primary voltage level V1, is generated, and the second secondary DC signal DC4 having the second secondary voltage level V3 (V1+V2), which is a voltage level obtained by adding the first primary voltage level V1 and the second primary voltage level V2, is generated. In the second generation state, as illustrated in FIG. 14, the first secondary DC signal DC3 having the first secondary voltage level V3 (V1+V2), which is the voltage level obtained by adding the first primary voltage level V1 and the second primary voltage level V2, is generated, and the second secondary DC signal DC4 having the second secondary voltage level V1, which is the same voltage level as the first primary voltage level V1, is generated.

The voltage adder 610 is electrically connected to the first voltage pulse generator 620 and the second voltage pulse generator 621. The first secondary DC signal DC3 generated by the voltage adder 610 may be supplied to the first voltage pulse generator 620, and the second secondary DC signal DC4 may be supplied to the second voltage pulse generator 621.

The first voltage pulse generator 620 may generate a first voltage pulse signal DC5 having the first secondary voltage level (V1 or V3) from the first secondary DC signal DC3 supplied from the voltage adder 610. The first voltage pulse signal DC5 may include a sequence of the first voltage pulses. In an embodiment, the sequence of the first voltage pulses has the same pulse pattern as the example illustrated in FIG. 5. The first voltage pulse generator 620 is electrically connected to the substrate bias electrode 202. The generated first voltage pulse signal DC5 may be supplied to the substrate bias electrode 202. By supplying the first voltage pulse signal DC5 to the substrate bias electrode 202, a bias pulse signal based on a direct current voltage is generated, and ion components in the plasma formed on the substrate W of the substrate support 11 can be drawn to a substrate bias electrode 202 side.

The second voltage pulse generator 621 may generate a second voltage pulse signal DC6 having the second secondary voltage level (V1 or V3) from the second secondary DC signal DC4 supplied from the voltage adder 610. The second voltage pulse signal DC6 may include a sequence of second voltage pulses. In an embodiment, the sequence of the second voltage pulses has the same pulse pattern as the example illustrated in FIG. 5. The second voltage pulse generator 621 is electrically connected to the ring bias electrode 203. The generated second voltage pulse signal DC6 may be supplied to the ring bias electrode 203. By supplying the second voltage pulse signal DC6 to the ring bias electrode 203, a bias pulse signal based on the direct current voltage is generated, and ion components in the plasma formed on the substrate W of the substrate support 11 can be drawn to a ring bias electrode 203 side.

In a case where the plasma sheath PS generated on the upper side of the substrate W and the ring assembly 112 is lower than the upper side of the substrate W on the upper side of the ring assembly 112 as illustrated in FIG. 7 during the plasma formation, the voltage level of the voltage pulse applied to the ring bias electrode 203 is set to be higher than the voltage level of the voltage pulse applied to the substrate bias electrode 202. That is, as illustrated in FIG. 13, the voltage adder 610 is switched to the first generation state, and the first secondary DC signal DC3 having the first secondary voltage level V1 and the second secondary DC signal DC4 having the second secondary voltage level V3 are generated. Then, the first voltage pulse signal DC5 having the first secondary voltage level V1 is supplied from the first voltage pulse generator 620 to the substrate bias electrode 202, and the voltage pulse signal DC6 having the second secondary voltage level V3 higher than the first secondary voltage level V1 is supplied from the second voltage pulse generator 621 to the ring bias electrode 203. As a result, as illustrated in FIG. 7, the plasma sheath PS approaches the substrate W in parallel (horizontally), and the angle (ion incidence angle) at which the ion component of the plasma enters the substrate W in the plane of the substrate W approaches perpendicular to the substrate W.

In an embodiment, as illustrated in FIG. 8, in a case where the plasma sheath PS is higher than the upper side of the substrate W on the upper side of the ring assembly 112, the voltage level of the voltage pulse applied to the substrate bias electrode 202 is set to be higher than the voltage level of the voltage pulse applied to the ring bias electrode 203. That is, as illustrated in FIG. 14, the voltage adder 610 is switched to the second generation state, and the first secondary DC signal DC3 having the first secondary voltage level V3 and the second secondary DC signal DC4 having the second secondary voltage level V1 are generated. Then, the first voltage pulse signal DC5 having the first secondary voltage level V3 higher than the second secondary voltage level V1 is supplied from the first voltage pulse generator 620 to the substrate bias electrode 202, and the voltage pulse signal DC6 having the second secondary voltage level V1 is supplied from the second voltage pulse generator 621 to the ring bias electrode 203. As a result, the plasma sheath PS approaches the substrate W in parallel (horizontally), and an angle (ion incidence angle) at which the ion component of the plasma enters the substrate W in a plane of the substrate W approaches perpendicular to the substrate W.

In the second embodiment as well, as in the first embodiment, the substrate bias electrode 202 and the ring bias electrode 203 of the substrate support 11 may be disposed at heights different from each other. The ring bias electrode 203 may be disposed at a position lower than the substrate bias electrode 202. The outer edge region 202a of the substrate bias electrode 202 may overlap the inner edge region 203a of the ring bias electrode 203 in the longitudinal direction. The ring bias electrode 203 may be disposed at a position higher than the substrate bias electrode 202.

In the first and second embodiments described above, the ring chuck electrode 201 illustrated in FIG. 3 has two electrodes 400 and 401 having different polarities from each other, but may have one unipolar electrode. The substrate bias electrode 202 and the ring bias electrode 203 may be each configured of a plurality of electrodes.

In the embodiments described above, while the capacitively coupled plasma apparatus is illustratively described, the present disclosure is not limited thereto, and may be applied to other plasma apparatuses. For example, an inductively coupled plasma apparatus may be used instead of the capacitively coupled plasma apparatus.

The embodiments of the present disclosure further include the following aspects.

### (Addendum 1)

A plasma processing apparatus including:
a plasma processing chamber;
a substrate support that is disposed in the plasma processing chamber, the substrate support including a base, an electrostatic chuck that is disposed on the base and has a substrate support surface and a ring support surface, and at least one annular member that is disposed on the ring support surface such that a substrate disposed on the substrate support surface is surrounded;
a substrate chuck electrode that is disposed below the substrate support surface in the electrostatic chuck;
at least one ring chuck electrode that is disposed below the ring support surface in the electrostatic chuck;
a substrate bias electrode that is disposed in the electrostatic chuck and is disposed below the substrate chuck electrode;
a ring bias electrode that is disposed in the electrostatic chuck and is disposed below the at least one ring chuck electrode;
a first voltage pulse generator configured to generate a sequence of first voltage pulses having a first voltage level;
a second voltage pulse generator configured to generate a sequence of second voltage pulses having a second voltage level; and
a switch configured to switch between a first connection state and a second connection state, the first connection state being a state where the first voltage pulse generator is electrically connected to the substrate bias electrode and the second voltage pulse generator is electrically connected to the ring bias electrode, and the second connection state being a state where the first voltage pulse generator is electrically connected to the ring bias electrode and the second voltage pulse generator is electrically connected to the substrate bias electrode.

### (Addendum 2)

The plasma processing apparatus according to Addendum 1, in which the switch includes
a rotatable member, and
a first wiring and a second wiring attached to the rotatable member,
the switch is configured to switch between the first connection state and the second connection state by rotation of the rotatable member,
the first connection state is a state where the first voltage pulse generator is electrically connected to the substrate bias electrode via the first wiring, and the second voltage pulse generator is electrically connected to the ring bias electrode via the second wiring, and
the second connection state is a state where the first voltage pulse generator is electrically connected to the ring bias electrode via the first wiring, and the second voltage pulse generator is electrically connected to the substrate bias electrode via the second wiring.

### (Addendum 3)

The plasma processing apparatus according to Addendum 1, in which the switch is an electric circuit.

### (Addendum 4)

The plasma processing apparatus according to any one of Addenda 1 to 3, in which the first voltage level and the second voltage level have a negative polarity.

### (Addendum 5)

The plasma processing apparatus according to any one of Addenda 1 to 4, in which an absolute value of the first voltage level is larger than an absolute value of the second voltage level.

### (Addendum 6)

The plasma processing apparatus according to any one of Addenda 1 to 5, in which the substrate bias electrode and the ring bias electrode are disposed at the same height.

### (Addendum 7)

The plasma processing apparatus according to any one of Addenda 1 to 5, in which the substrate bias electrode and the ring bias electrode are disposed at heights different from each other.

### (Addendum 8)

The plasma processing apparatus according to Addendum 7, in which the ring bias electrode is disposed at a position lower than the substrate bias electrode.

### (Addendum 9)

The plasma processing apparatus according to Addendum 8, in which the substrate bias electrode has an outer edge region, and the ring bias electrode has an inner edge region that overlaps the outer edge region of the substrate bias electrode in a longitudinal direction.

### (Addendum 10)

The plasma processing apparatus according to any one of Addenda 1 to 9, in which the ring chuck electrode includes
an inner ring chuck electrode to which a first ring chuck voltage having a first polarity is applied, and
an outer ring chuck electrode to which a second ring chuck voltage having a second polarity is applied.

(Addendum 11)

A plasma processing apparatus including:
a plasma processing chamber;
a substrate support that is disposed in the plasma processing chamber, the substrate support including a base, an electrostatic chuck that is disposed on the base and has a substrate support surface and a ring support surface, and at least one annular member that is disposed on the ring support surface such that a substrate disposed on the substrate support surface is surrounded;
a substrate chuck electrode that is disposed below the substrate support surface in the electrostatic chuck;
at least one ring chuck electrode that is disposed below the ring support surface in the electrostatic chuck;
a substrate bias electrode that is disposed in the electrostatic chuck and is disposed below the substrate chuck electrode;
a ring bias electrode that is disposed in the electrostatic chuck and is disposed below the at least one ring chuck electrode;
a first DC power supply configured to generate a first primary DC signal having a first primary voltage level;
a second DC power supply configured to generate a second primary DC signal having a second primary voltage level;
a voltage adder that is configured to generate a first secondary DC signal having a first secondary voltage level and a second secondary DC signal having a second secondary voltage level from the first primary DC signal and the second primary DC signal, and is configured to switch between a first generation state and a second generation state,
the first generation state being a state where
   the first secondary DC signal is generated such that the first secondary voltage level has the same voltage level as the first primary voltage level, and
   the second secondary DC signal is generated such that the second secondary voltage level has a voltage level obtained by adding the first primary voltage level and the second primary voltage level, and
the second generation state being a state where
   the first secondary DC signal is generated such that the first secondary voltage level has a voltage level obtained by adding the first primary voltage level and the second primary voltage level, and
   the second secondary DC signal is generated such that the second secondary voltage level has the same voltage level as the first primary voltage level;
a first voltage pulse generator that is electrically connected to the substrate bias electrode and is configured to generate a sequence of first voltage pulses having the first secondary voltage level from the first secondary DC signal; and
a second voltage pulse generator that is electrically connected to the ring bias electrode and is configured to generate a sequence of second voltage pulses having the second secondary voltage level from the second secondary DC signal.

### (Addendum 12)

The plasma processing apparatus according to Addendum 11, in which the first primary voltage level and the second primary voltage level have a negative polarity.

### (Addendum 13)

The plasma processing apparatus according to Addendum 11 or 12, in which an absolute value of the first primary voltage level is larger than an absolute value of the second primary voltage level.

### (Addendum 14)

The plasma processing apparatus according to Addendum 13, in which the absolute value of the first primary voltage level is 5 times or more the absolute value of the second primary voltage level.

### (Addendum 15)

The plasma processing apparatus according to any one of Addenda 11 to 14, in which the substrate bias electrode and the ring bias electrode are disposed at the same height.

### (Addendum 16)

The plasma processing apparatus according to any one of Addenda 11 to 14, in which the substrate bias electrode and the ring bias electrode are disposed at heights different from each other.

### (Addendum 17)

The plasma processing apparatus according to Addendum 16, in which the ring bias electrode is disposed at a position lower than the substrate bias electrode.

### (Addendum 18)

The plasma processing apparatus according to Addendum 17, in which the substrate bias electrode has an outer edge region, and
the ring bias electrode has an inner edge region that overlaps the outer edge region of the substrate bias electrode in a longitudinal direction.

### (Addendum 19)

The plasma processing apparatus according to any one of Addenda 11 to 18, in which the ring chuck electrode includes
an inner ring chuck electrode to which a first ring chuck voltage having a first polarity is applied, and
an outer ring chuck electrode to which a second ring chuck voltage having a second polarity is applied.

Each of the above embodiments is described for the purpose of description, and it is not intended to limit the scope of the present disclosure. Each of the above embodiments may be modified in various ways without departing from the scope and gist of the present disclosure. For example, some constitutional elements in one embodiment are able to be added to other embodiments. In addition, some configuration elements in one embodiment are able to be replaced with corresponding configuration elements in another embodiment.

According to one exemplary embodiment of the present disclosure, it is possible to provide a technique that can improve the in-plane uniformity of the substrate in the plasma processing.

What is claimed is:

1. A plasma processing apparatus comprising:
a plasma processing chamber;
a substrate support disposed in the plasma processing chamber, the substrate support including a base, an electrostatic chuck and at least one annular member, the electrostatic chuck disposed on the base and having a substrate support surface and a ring support surface, the at least one annular member disposed on the ring support surface such that a substrate disposed on the substrate support surface is surrounded;
a substrate chuck electrode disposed below the substrate support surface in the electrostatic chuck;
at least one ring chuck electrode disposed below the ring support surface in the electrostatic chuck;
a substrate bias electrode disposed in the electrostatic chuck and disposed below the substrate chuck electrode;
a ring bias electrode disposed in the electrostatic chuck and disposed below the at least one ring chuck electrode;
a first voltage pulse generator configured to generate a sequence of first voltage pulses, the sequence of first voltage pulses having a first voltage level;
a second voltage pulse generator configured to generate a sequence of second voltage pulses, the sequence of second voltage pulses having a second voltage level; and
a switch configured to switch between a first connection state and a second connection state, the first connection state being a state where the first voltage pulse generator is electrically connected to the substrate bias electrode and the second voltage pulse generator is electrically connected to the ring bias electrode, and the second connection state being a state where the first voltage pulse generator is electrically connected to the ring bias electrode and the second voltage pulse generator is electrically connected to the substrate bias electrode.

2. The plasma processing apparatus according to claim 1, wherein
the switch includes
a rotatable member, and
a first wiring and a second wiring attached to the rotatable member,
the switch is configured to switch between the first connection state and the second connection state by rotation of the rotatable member,
the first connection state being a state where the first voltage pulse generator is electrically connected to the substrate bias electrode via the first wiring, and the second voltage pulse generator is electrically connected to the ring bias electrode via the second wiring, and
the second connection state being a state where the first voltage pulse generator is electrically connected to the ring bias electrode via the first wiring, and the second voltage pulse generator is electrically connected to the substrate bias electrode via the second wiring.

3. The plasma processing apparatus according to claim 1, wherein the switch is an electric circuit.

4. The plasma processing apparatus according to claim 1, wherein the first voltage level and the second voltage level have a negative polarity.

5. The plasma processing apparatus according to claim 4, wherein an absolute value of the first voltage level is larger than an absolute value of the second voltage level.

6. The plasma processing apparatus according to claim 1, wherein the substrate bias electrode and the ring bias electrode are disposed at the same height.

7. The plasma processing apparatus according to claim 1, wherein the substrate bias electrode and the ring bias electrode are disposed at heights different from each other.

8. The plasma processing apparatus according to claim 7, wherein the ring bias electrode is disposed at a position lower than the substrate bias electrode.

9. The plasma processing apparatus according to claim 8, wherein
the substrate bias electrode has an outer edge region, and
the ring bias electrode has an inner edge region that overlaps the outer edge region of the substrate bias electrode in a longitudinal direction.

10. The plasma processing apparatus according to claim 1, wherein the ring chuck electrode includes
an inner ring chuck electrode to which a first ring chuck voltage having a first polarity is applied, and
an outer ring chuck electrode to which a second ring chuck voltage having a second polarity is applied.

11. A plasma processing apparatus comprising:
a plasma processing chamber;
a substrate support disposed in the plasma processing chamber, the substrate support including a base, an electrostatic chuck and at least one annular member, the electrostatic chuck disposed on the base and having a substrate support surface and a ring support surface, and the at least one annular member disposed on the ring support surface such that a substrate disposed on the substrate support surface is surrounded;
a substrate chuck electrode disposed below the substrate support surface in the electrostatic chuck;
at least one ring chuck electrode disposed below the ring support surface in the electrostatic chuck;
a substrate bias electrode disposed in the electrostatic chuck and disposed below the substrate chuck electrode;
a ring bias electrode disposed in the electrostatic chuck and disposed below the at least one ring chuck electrode;
a first DC power supply configured to generate a first primary DC signal, the first primary DC signal having a first primary voltage level;
a second DC power supply configured to generate a second primary DC signal, the second primary DC signal having a second primary voltage level;
a voltage adder configured to generate a first secondary DC signal having a first secondary voltage level and a second secondary DC signal having a second secondary voltage level, from the first primary DC signal and the second primary DC signal, and configured to switch between a first generation state and a second generation state,
the first generation state being a state where
the first secondary DC signal is generated such that the first secondary voltage level has the same voltage level as the first primary voltage level, and
the second secondary DC signal is generated such that the second secondary voltage level has a voltage level obtained by adding the first primary voltage level and the second primary voltage level, and
the second generation state being a state where
the first secondary DC signal is generated such that the first secondary voltage level has a voltage level obtained by adding the first primary voltage level and the second primary voltage level, and
the second secondary DC signal is generated such that the second secondary voltage level has the same voltage level as the first primary voltage level;
a first voltage pulse generator electrically connected to the substrate bias electrode and configured to generate a sequence of first voltage pulses from the first secondary DC signal, the sequence of first voltage pulses having the first secondary voltage level; and
a second voltage pulse generator electrically connected to the ring bias electrode and configured to generate a sequence of second voltage pulses from the second secondary DC signal, the sequence of second voltage pulses having the second secondary voltage level.

12. The plasma processing apparatus according to claim 11, wherein the first primary voltage level and the second primary voltage level have a negative polarity.

13. The plasma processing apparatus according to claim 12, wherein an absolute value of the first primary voltage level is larger than an absolute value of the second primary voltage level.

14. The plasma processing apparatus according to claim 13, wherein the absolute value of the first primary voltage level is 5 times or more the absolute value of the second primary voltage level.

15. The plasma processing apparatus according to claim 11, wherein the substrate bias electrode and the ring bias electrode are disposed at the same height.

16. The plasma processing apparatus according to claim 11, wherein the substrate bias electrode and the ring bias electrode are disposed at heights different from each other.

17. The plasma processing apparatus according to claim 16, wherein the ring bias electrode is disposed at a position lower than the substrate bias electrode.

18. The plasma processing apparatus according to claim 17, wherein
the substrate bias electrode has an outer edge region, and
the ring bias electrode has an inner edge region that overlaps the outer edge region of the substrate bias electrode in a longitudinal direction.

19. The plasma processing apparatus according to claim 11, wherein the ring chuck electrode includes
an inner ring chuck electrode to which a first ring chuck voltage having a first polarity is applied, and
an outer ring chuck electrode to which a second ring chuck voltage having a second polarity is applied.
